(19) United States
(12) Patent Application Publication
(10) Pub. No.: US 2025/0285699 A1
(43) Pub. Date: Sep. 11, 2025

(54) TEST DEVICE AND TEST METHOD FOR MEASURING TIMING SPECIFICATIONS OF MEMORY DEVICE

(71) Applicant: SAMSUNG ELECTRONICS CO., LTD., Suwon-si (KR)

(72) Inventors: YEONHO JUNG, Suwon-si (KR); DOHUI KIM, Suwon-si (KR); Soohoh SEOL, Suwon-si (KR); nam hoon KIM, Suwon-si (KR); MIJOUNG KIM, Suwon-si (KR); HYUN-JIN SHIN, Suwon-si (KR); Jaeho LEE, Suwon-si (KR)

(73) Assignee: SAMSUNG ELECTRONICS CO., LTD., Suwon-si (KR)

(21) Appl. No.: 18/970,531

(22) Filed: Dec. 5, 2024

(30) Foreign Application Priority Data
Mar. 8, 2024 (KR) 10-2024-0033402

(51) Int. Cl. G11C 29/10; G01R 31/3177

(52) U.S. Cl. CPC G11C 29/10; G01R 31/3177

(57) ABSTRACT

A test device for a memory device includes a first exclusive OR (XOR) gate configured to output a first operation signal by performing an XOR operation between a clock signal and an output signal output from the memory device, an oscillator configured to output an oscillation signal, and an output circuit configured to determine a period of the oscillation signal. The output circuit may be configured to count a number of rising edges of the oscillation signal while the first operation signal is maintained at a high level, and determine an access time of the memory device based on the counted number of the rising edges, and a period of the oscillation signal.

### CROSS-REFERENCE TO RELATED APPLICATION(S)

This application is based on and claims priority under 35 USC § 119 to Korean Patent Application No. 10-2024-0033402, filed on Mar. 8, 2024, in the Korean Intellectual Property Office, the disclosure of which is herein incorporated by reference in its entirety.

### BACKGROUND

Example embodiments relate to a test device and a test method for measuring timing specifications of a memory device.

Semiconductor memory devices are classified into volatile memory devices, such as static random access memory (SRAM) devices or dynamic random access memory (DRAM) devices, and nonvolatile memory devices, such as flash memory devices, phase-change random access memory (PRAM) devices, magnetic random access memory (MRAM) devices, resistive random access memory (RRAM) devices, or ferroelectric random access memory (FRAM) devices. Volatile memory devices lose their stored data when their power supplies are interrupted, while nonvolatile memory devices retain their stored data even when their power supplies are interrupted.

In memory devices, defects may occur due to various factors. Various defects in memory devices, such as write defects in memory cells, may occur probabilistically and thus memory devices need to be tested.

For example, there is a growing demand for test devices and test methods for accurately measuring timing specifications including a read speed, an access time, a setup time, or a hold time of memory devices to ensure normal operations of the memory devices.

### SUMMARY

Example embodiments provide a test device for accurately measuring timing specifications of a memory device.

According to one or more example embodiments, a test device for a memory device includes a first exclusive OR (XOR) gate configured to output a first operation signal by performing an XOR operation between a clock signal and an output signal output from the memory device, an oscillator configured to output an oscillation signal, and an output circuit configured to determine a period of the oscillation signal. The output circuit may be configured to count a number of rising edges of the oscillation signal while the first operation signal is maintained at a high level, and determine an access time of the memory device based on the counted number of the rising edges, and a period of the oscillation signal.

According to one or more example embodiments, a test method for a memory device includes determining a period of an oscillation signal, output from an oscillator; counting a number of rising edges of the oscillation signal that occur while a first operation signal, which is a result of an exclusive OR (XOR) operation between a clock signal and an output signal output from the memory device, is maintained at a high level, and determining an access time of the memory device based on the counted number of the rising edges, and the period of the oscillation signal.

According to one or more example embodiments, a test device for a memory device includes an oscillator configured to output an oscillation signal, a first exclusive OR (XOR) gate configured to perform an XOR operation between a clock signal and an output signal output from the memory device, a first chain circuit and a second chain circuit configured to output delayed clocks in which different delay times are respectively applied to the clock signal, a second XOR gate configured to perform an XOR operation between a signal output from the first chain circuit and a signal output from the second chain circuit, and an output circuit configured to determine a period of the oscillation signal. The output circuit may be configured to determine an access time of the memory device based on a number of rising edges of the oscillation signal that occur while a first operation signal output from the first XOR gate is maintained at a high level, and the period of the oscillation signal, and determine a unit delay time based on a number of rising edges of the oscillation signal that occur while a second operation signal output from the second XOR gate is maintained at a high level.

### BRIEF DESCRIPTION OF DRAWINGS

The above and other objects and features of the present disclosure will become apparent by describing in detail example embodiments thereof with reference to the accompanying drawings.

FIG. 1 is a block diagram of a memory system according to one or more example embodiments.

FIG. 2A is a circuit diagram of a memory system including a test device for measuring an access time of a memory device according to one or more example embodiments.

FIG. 2B is a diagram illustrating a configuration in which the test device of FIG. 2A determines an access time of the memory device.

FIG. 3A is a circuit diagram of a memory system including a test device, the test device including a first chain circuit and a second chain circuit, according to one or more example embodiments.

FIG. 3B is a diagram illustrating a configuration in which a control logic circuit according to one or more example embodiments controls a first chain circuit and a second circuit to output delay clocks to which different delay times are applied.

FIG. 3C is a diagram illustrating a configuration in which the test device of FIG. 3A determines a unit delay time of the first chain circuit and the second chain circuit.

FIG. 4A is a circuit diagram illustrating a configuration in which a test device outputs a third delay clock and a fourth delay clock, to which different delay times are applied, through a first chain circuit.

FIG. 4B is a diagram illustrating a configuration in which a first threshold setup time is determined through an output circuit when the test device of FIG. 4A outputs a third delay clock through the first chain circuit.

FIG. 4C is a diagram illustrating a configuration in which a second threshold setup time is determined through an output circuit when the test device of FIG. 4A outputs a fourth delay clock through the first chain circuit.

FIG. 5A is a circuit diagram illustrating a configuration in which a test device according to one or more example embodiments outputs a fifth delay clock and a sixth delay clock, to which different delay times are applied, through a first chain circuit.

FIG. 5B is a diagram illustrating a configuration in which first threshold hold time is determined through an output circuit when the test device of FIG. 5A outputs a third delay clock through the first chain circuit.

FIG. 5C is a diagram illustrating a configuration in which second threshold hold time is determined through the output circuit when the test device of FIG. 5A outputs a fourth delay clock through the first chain circuit.

FIG. 6A is a circuit diagram illustrating a configuration of the first chain circuit according to one or more example embodiments.

FIG. 6B is a circuit diagram illustrating a configuration of a first internal multiplexer and the second internal multiplexer of the first chain circuit of FIG. 6A.

FIG. 7 is a circuit diagram illustrating a memory system including a test device further including a second multiplexer according to one or more example embodiments.

FIG. 8 is a circuit diagram illustrating a memory system including a test device further including a third multiplexer according to one or more example embodiments.

FIG. 9 is a flowchart illustrating a test method for determining an access time of a memory device according to one or more example embodiments.

FIG. 10 is a flowchart illustrating a method for determining a unit delay time of a first chain circuit and a second chain circuit included in a test device according to one or more example embodiments.

FIG. 11 is a flowchart illustrating a test method for determining a setup time of a memory device based on unit delay time according to one or more example embodiments.

FIG. 12 is a flowchart illustrating a test method for determining a hold time of a memory device based on the unit delay time according to one or more example embodiments.

### DETAILED DESCRIPTION

Hereinafter, example embodiments will be described with reference to the accompanying drawings.

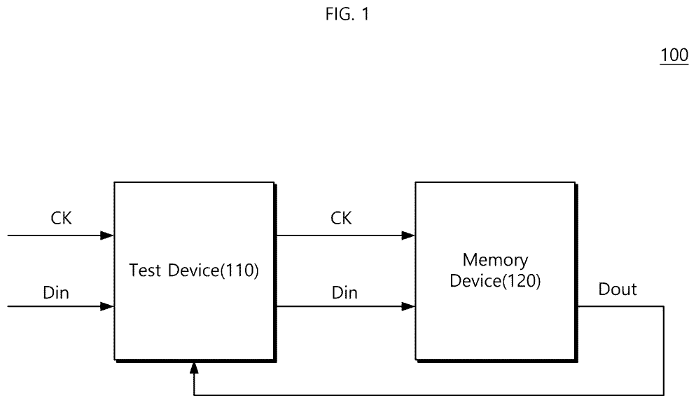

FIG. 1 is a block diagram illustrating a memory system according to one or more example embodiments.

Referring to FIG. 1, a memory system 100 according to one or more example embodiments may include a test device 110 and a memory device 120.

The memory system 100 may include a memory device 120 configured to store input data.

For example, the memory device 120 may store data input from an outside. In addition, the memory device 120 may output stored data in response to a write request input from the outside.

The memory device 120 may include a nonvolatile memory such as, for example but not limited to, a flash memory, a magnetic RAM (MRAM), a ferroelectric RAM (FeRAM), a phase-change RAM (PRAM), or a resistive RAM (ReRAM), but example embodiments are not limited thereto. Examples of the memory device 120 may include, for example but not limited to, a dynamic random access memory (DRAM) such as a double data rate synchronous dynamic random access memory (DDR SDRAM), a low power double data rate (LPDDR) SDRAM, a graphics double data rate (GDDR) SDRAM, or a Rambus dynamic random access memory (RDRAM).

In addition, the memory system 100 may include a test device 110 electrically connected to the memory device 120.

For example, the test device 110 may transmit a clock signal CK and an input signal Din to the memory device 120. In addition, the test device 110 may obtain an output signal Dout output from the memory device 120.

The test device 110 may perform a test operation on the memory device 120.

For example, the test device 110 may determine (or measure) timing specifications of the memory device 120 using at least a portion of the clock signal CK, the input signal Din, and the output signal Dout.

According to one or more example embodiments, the test device 110 may determine an access time of the memory device 120 based on a result of an exclusive OR (XOR) operation between the clock signal CK and the output signal Dout.

For example, the test device 110 may determine the access time of the memory device 120 by performing a logical conjunction (AND) operation on the result of an XOR operation between the clock signal CK and the output signal Dout and an oscillation signal output from an oscillator.

For example, the access time may be understood as corresponding to a time taken for the memory device 120 to output an output signal Dout in response to a clock signal CK from the memory device 120 in a state in which the input signal Din is input to the memory device 120.

For example, the access time may be understood as corresponding to a time from when the clock signal CK is input to the memory device 120 to when the output signal Dout is output from the memory device 120, in a state in which the input signal Din is input to the memory device 120.

For example, the access time may be understood as corresponding to a time taken for the memory device 120 to output data in response to an input command or store data in response to a write command.

According to one or more example embodiments, the test device 110 may determine (or measure) at least a portion of a setup time and a hold time of the memory device 120 using the clock signal CK and input signal Din.

For example, the test device 110 may determine a unit delay time based on a result of an XOR operation between delay clocks generated by applying different delay times to the clock signal CK.

For example, the test device 110 may determine a unit delay time by performing a logical conjunction (AND) operation on a result of an XOR operation between the delay clocks, generated by applying different delay times to the clock signal CK, and the oscillation signal output from the oscillator.

Furthermore, the test device 110 may determine at least a portion of the setup time and the hold time of the memory device 120 based on the clock signal CK, the input signal Din, and the unit delay time.

For example, the test device 110 may determine the setup time and/or the hold time of the memory device 120 based on the XOR operation result between the clock signal CK with a fixed delay time and the input signal Din, and the unit delay time.

For example, the setup time of the memory device 120 may refer to a minimum time during which a logic level of the input signal Din should be maintained before a rising or falling edge of the clock signal CK applied to the memory device 120.

For example, the setup time of the memory device 120 may refer to a minimum amount of time required for the input signal Din to be determined as having a logic low level or a logic high level.

The hold time of a memory device 120 may refer to a minimum amount of time during which a logic level of the input signal Din should be maintained after the rising or falling edge of the clock signal CK applied to the memory device 120.

For example, the hold time of the memory device 120 may refer to a minimum time required for the input signal Din to be output.

Based on the above-described configurations, the test device 110 may measure the timing specifications of the memory device 120 based on at least a portion of the input signal Din and clock signal CK input to the memory device 120 and the output signal Dout output from the memory device 120.

Therefore, the test device 110 may also be referred to as, for example, a built-in self-test (BIST) device, a design for test (DFT) device, or the like.

In addition, referring to the above-described configurations, the test device 110 may measure the timing specifications of the memory device 120 based on the oscillation signal output from the oscillator.

As a result, the memory system 100 (or the test device 110) according to one or more example embodiments may accurately measure the timing specifications of the memory device 120.

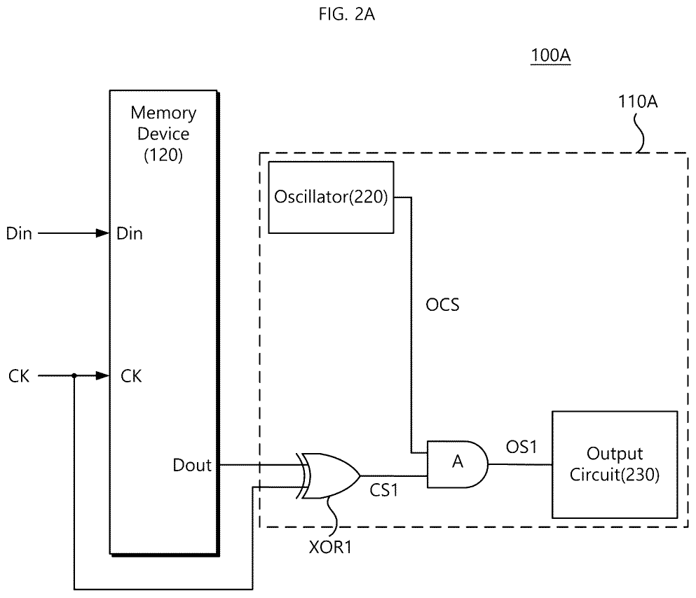

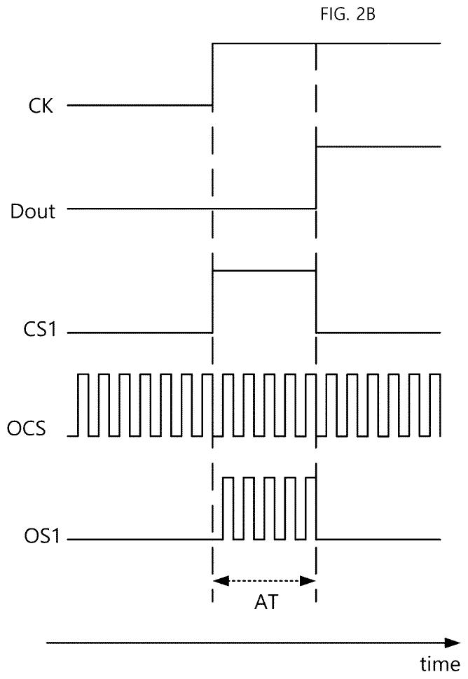

FIG. 2A is a circuit diagram of a memory system including a test device for measuring a access time of a memory device according to one or more example embodiments, and FIG. 2B is a diagram illustrating a configuration in which the test device of FIG. 2A determines the access time of the memory device.

Referring to FIGS. 2A and 2B, a memory system 100A according to one or more example embodiments may include a test device 110A and a memory device 120.

The memory system 100A illustrated in FIG. 2A may be understood as an example of the memory system 100 illustrated in FIG. 1.

Therefore, the same or substantially the same components may be represented by the same reference numerals, and redundant descriptions are omitted to avoid repetition.

Referring to FIG. 2A, the test device 110A according to one or more example embodiments may include an oscillator 220, a first XOR gate XOR1, and an output circuit 230. In addition, the test device 110A may further include an AND gate A electrically connected between the first XOR gate XOR1 and the oscillator 220, and the output circuit 230.

The test device 110A may include the first XOR gate XOR1 configured to perform an exclusive OR (XOR) operation between the clock signal CK and the output signal Dout output from the memory device 120.

The output signal Dout may be understood as a data signal output by the memory device 120 in response to the input signal Din and the clock signal CK.

For example, the first XOR gate XOR1 may perform an XOR operation between the clock signal CK and the output signal Dout to output a first operation signal CS1.

Referring to FIG. 2B, for example, the first operation signal CS1 may have a waveform maintained at a high level (for example, “1”) during a period AT, which is from a time when a rising edge of the clock signal CK occurs to a time when a rising edge of the output signal Dout occurs.

In addition, the test device 110A may include the oscillator 220 configured to output an oscillation signal OCS.

The oscillator 220 according to one or more example embodiments may output an oscillation signal OCS having a specified period. For example, the oscillator 220 may output an oscillation signal OCS having rising edges that occur according to the specified period.

For example, the oscillator 220 may include a plurality of inverters connected in series. The oscillator 220 may be referred to as a ring oscillator. However, the type and configuration of the oscillator 220 are not limited to the above-described example, and the oscillator 220 may be understood as having various types and configurations that may generate an oscillation signal OCS having a specific period.

In addition, the test device 110A may include the output circuit 230 configured to determine a period of the oscillation signal OCS.

For example, the output circuit 230 may divide the oscillation signal OCS to determine the period of the oscillation signal OCS.

For example, the output circuit 230 may divide the oscillation signal OCS to determine that the period of the oscillation signal OCS is 100 picoseconds (ps). For example, the output circuit 230 may be referred to as a divider.

In addition, the output circuit 230 may count a number of rising edges of a first output signal OS1 during the period AT.

For example, the test device 110A may include an AND gate A configured to perform a logical conjunction (AND) operation between the first operation signal CS1 and the oscillation signal OCS.

For example, the AND gate A may output the first output signal OS1, which is a result of the AND operation between the first operation signal CS1 and the oscillation signal OCS.

Referring to FIG. 2B, the first output signal OS1 may have the same waveform as the waveform of the oscillation signal OCS while the first operation signal CS1 is maintained at a high level. While the output circuit 230 may divide the oscillation signal OCS to determine the period of the oscillation signal OCS, for example, 100 ps, division of the oscillation signal OCS is omitted for brevity of description.

For example, the output circuit 230 may count a number of rising edges of the oscillation signal OCS (or the first output signal OS1) that occur while the first operation signal CS1 is maintained at a high level.

For example, the output circuit 230 may be referred as a counter configured to count a number of rising edges of an input signal thereof.

Furthermore, the output circuit 230 may determine the access time of the memory device 120 based on the number of rising edges of the oscillation signal OCS counted while the first operation signal CS1 is maintained at a high level.

For example, the output circuit 230 may determine an access time of the memory device 120 based on the number of rising edges of the oscillation signal OCS, counted while the first operation signal CS1 is maintained at a high level, and the period of the oscillation signal OCS.

For example, referring to FIG. 2B, the output circuit 230 may determine that five rising edges of the oscillation signal OCS occurs while the first operation signal CS1 is maintained at a high level.

Furthermore, the output circuit 230 may determine the access time of the memory device 120 to be 500 ps, based on five rising edges of the oscillation signal OCS that occur while the first operation signal CS1 is maintained at a high level and the period of the oscillation signal OCS being 100 ps.

For example, the output circuit 230 may determine that the time taken for the memory device 120 to output an output signal Dout in response to the rising edge of the clock signal CK in a state, in which the input signal Din is input to the memory device 120, is 500 ps.

Referring to the above-described configurations, the test device 110A according to one or more example embodiments may divide the oscillation signal OCS to determine the period of the oscillation signal OCS.

In addition, the test device 110A may measure the access time of the memory device 120 using the determined period and the result of the XOR operation between the clock signal CK and the output signal Dout.

As a result, the memory system 100A according to one or more example embodiments may improve the accuracy of the operation or process of measuring the access time of the memory device 120.

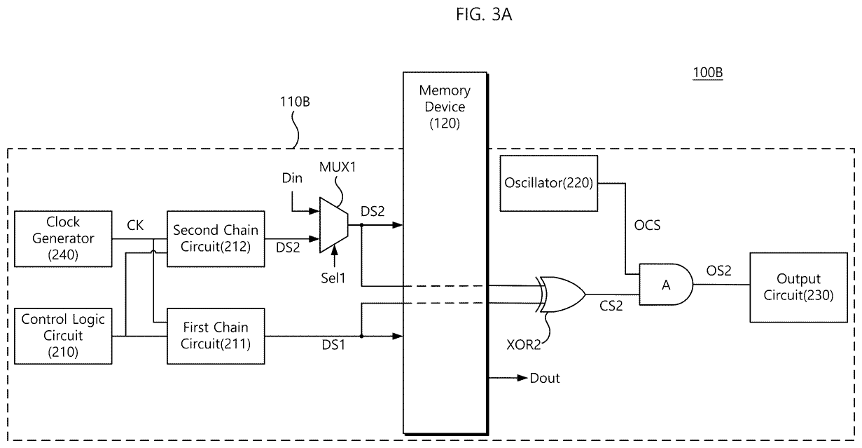

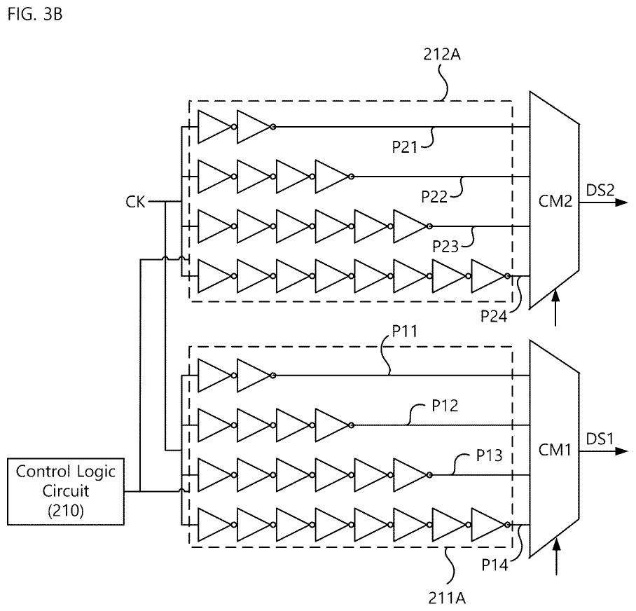

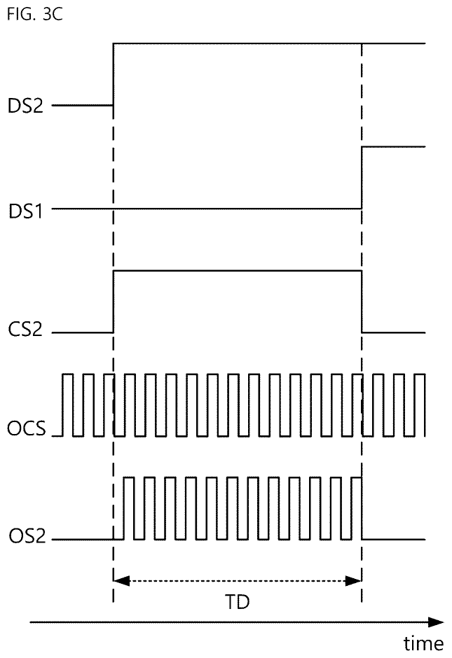

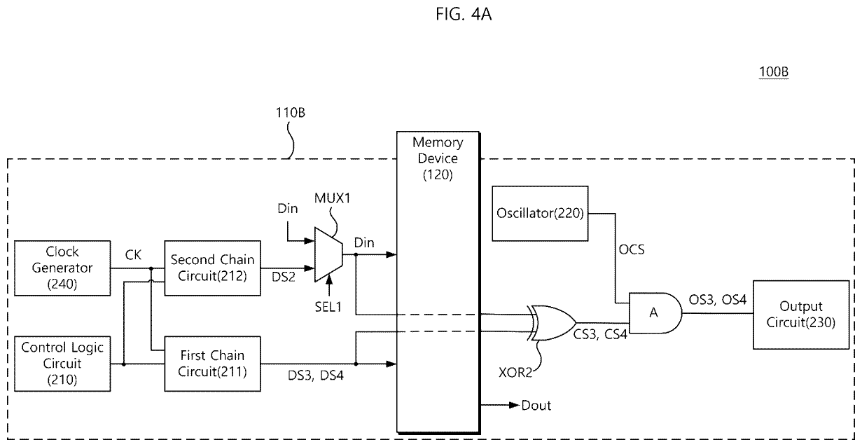

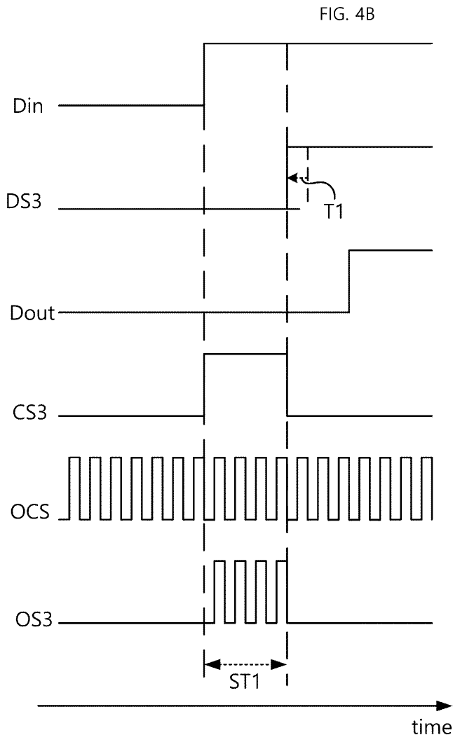

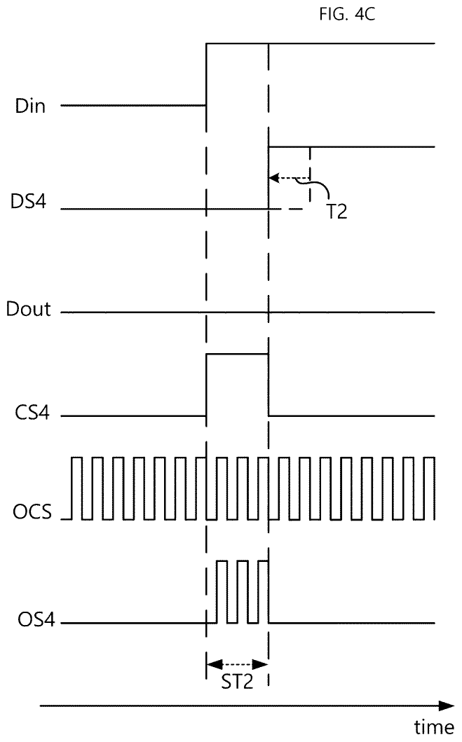

FIG. 3A is a circuit diagram of a memory system 100B including a test device including a first chain circuit and a second chain circuit according to one or more example embodiments. FIG. 3B is a diagram illustrating a configuration in which a control logic circuit according to one or more example embodiments controls a first chain circuit and a second circuit to output delay clocks to which different delay times are applied. FIG. 3C is a diagram illustrating a configuration in which the test device of FIG. 3A determines a unit delay time of the first chain circuit and the second chain circuit. FIG. 4A is a circuit diagram illustrating a configuration in which a test device outputs a third delay clock and a fourth delay clock, to which different delay times are applied, through a first chain circuit. FIG. 4B is a diagram illustrating a configuration in which a first threshold setup time is determined through an output circuit when the test device of FIG. 4A outputs a third delay clock through the first chain circuit. FIG. 4C is a diagram illustrating a configuration in which a second threshold setup time is determined through an output circuit when the test device of FIG. 4A outputs a fourth delay clock through the first chain circuit.

Referring to FIGS. 3A to 3C and FIGS. 4A to 4C, the memory system 100B according to one or more example embodiments may include a test device 110B and a memory device 120.

The test device 110B may include a first chain circuit 211, a second chain circuit 212, a control logic circuit 210, a first multiplexer MUX1, a second XOR gate XOR2, an oscillator 220, an AND gate A, and an output circuit 230.

The test device 110B according to one or more example embodiments may further include a clock generator 240 configured to generate a clock signal CK. The clock generator 240 may generate a clock signal CK having a specified frequency using a phase locked loop (PLL) circuit and/or an oscillator circuit.

The memory system 100B illustrated in FIGS. 3A and 4A may be understood as an example of the memory system 100 illustrated in FIG. 1.

Therefore, the same or substantially the same components may be represented by the same reference numerals, and redundant descriptions are omitted to avoid repetition.

According to one or more example embodiments, the test device 110B may include the first chain circuit 211 and the second chain circuit 212, each being configured to the clock signal CK.

For example, the test device 110B may include the first chain circuit 211 configured to receive the clock signal CK and including a plurality of inverters. In addition, the test device 110B may include a second chain circuit 212 configured to receive the clock signal CK and including a plurality of inverters.

For example, the first chain circuit 211 and the second chain circuit 212 may be implemented with substantially the same configuration. For example, at least a portion of the plurality of inverters included in each of the first chain circuit 211 and the second chain circuit 212 may be connected in series.

In addition, the test device 110B may include the control logic circuit 210 electrically connected to the first chain circuit 211 and the second chain circuit 212.

For example, the control logic circuit 210 may control at least a portion of the first chain circuit 211 and the second chain circuit 212 to output delay clocks DS1 and DS2 obtained by applying different delay times to the clock signal CK.

According to one or more example embodiments, the control logic circuit 210 may control the first chain circuit 211 to output a first delay clock DS1 to which a first delay time, equal to a first integer multiple of a unit delay time, is applied.

For example, the control logic circuit 210 may control the first chain circuit 211 to output the clock signal CK, input to the first chain circuit 211, through an electrical path including at least a portion of the plurality of inverters included in the first chain circuit 211.

The unit delay time may be understood as corresponding to a delay time caused by one of the plurality of inverters.

Referring to FIG. 3B, the control logic circuit 210 may control a first chain multiplexer CM1 to output, as the first delay clock DS1, the clock signal CK, input to a first chain circuit 211A, through a 1-4-th path P14 including eight inverters connected in series.

For example, the control logic circuit 210 may control the first chain circuit 211A to output, through the first chain multiplexer CM1, the first delay clock DS1, in which a first delay time equal to 8 times the unit delay time is applied to the clock signal CK.

In addition, the control logic circuit 210 may control the second chain circuit 212 to output a second delay clock DS2 to which a second delay time, equal to a second integer multiple of the unit delay time, is applied.

For example, the control logic circuit 210 may control the second chain circuit 212 to output the clock signal CK, input to the second chain circuit 212, through an electrical path including at least a portion of the plurality of inverters included in the second chain circuit 212.

Referring to FIG. 3B, the control logic circuit 210 may control a second chain multiplexer CM2 to output, as the second delay clock DS2, the clock signal CK, input to a second chain circuit 212A, through a 2-1-th path P21 including two inverters connected in series.

For example, the control logic circuit 210 may control the second chain circuit 212A to output, through the second chain multiplexer CM2, the second delay clock DS2, in which a delay time, equal to 2 times the unit delay time, is applied to the clock signal CK.

In addition, the test device 110B may include the first multiplexer MUX1 electrically connected between the second chain circuit 212 and the memory device 120.

For example, the first multiplexer MUX1 may selectively output one of the input signal Din and the second delay clock DS2.

For example, the first multiplexer MUX1 may output the second delay clock DS2 to the memory device 120 in response to a first select signal SEL1.

In addition, the test device 110B may include the second XOR gate XOR2 configured to perform an XOR operation between a signal, output from the first chain circuit 211, and a signal output from the second chain circuit 212.

For example, the test device 110B may include the second XOR gate XOR2 configured to perform an XOR operation between a signal, output from the first chain circuit 211, and a signal output from the first multiplexer MUX1.

According to one or more example embodiments, the second XOR gate XOR2 may perform an XOR operation between the first delay clock DS1 and the second delay clock DS2.

For example, the second XOR gate XOR2 may output a second operation signal CS2 as a result of an XORing the first delay clock DS1 and the second delay clock DS2.

For example, referring to FIG. 3C, the second XOR gate XOR2 may output a second operation signal CS2 having a waveform maintained at a high level (for example, “1”) in a period TD, which is from a time a rising edge of the second delay clock DS2 occurs to a time a rising edge of the first delay clock DS1 occurs.

In addition, the output circuit 230 may count a number of rising edges of a second output signal OS2 during the period TD.

For example, the test device 110B may include an AND gate A configured to perform an AND operation between the second operation signal CS2 and the oscillation signal OCS. For example, the AND gate A may output the second output signal OS2, based on a result of the AND operation between the second operation signal CS2 and the oscillation signal OCS.

Referring to FIG. 3C, the second output signal OS2 may have the same waveform as the waveform of the oscillation signal OCS while the second operation signal CS2 is maintained at a high level.

The output circuit 230 may count the number of rising edges of the oscillation signal OCS that occur while the second operation signal CS2 is maintained at a high level.

Furthermore, the output circuit 230 may determine a unit delay time based on the number of rising edges of the oscillation signal OCS that are counted while the second operation signal CS2 is maintained at a high level.

For example, the output circuit 230 may determine a unit delay time corresponding to a delay time caused by a single inverter, based on the number of rising edges of the oscillation signal OCS that are counted while the second operation signal CS2 is maintained at a high level and a period of the oscillation signal OCS.

For example, referring to FIG. 3C, the output circuit 230 may determine that 12 rising edges of the oscillation signal OCS occur while the second operation signal CS2 is maintained at a high level.

In addition, the output circuit 230 may determine that a time difference TD between the first delay clock DS1 and the second delay clock DS2 is 1200 ps, based on 12 rising edges of the oscillation signal OCS that occur while the second operation signal CS2 is maintained at a high level and a period of the oscillation signal OCS being 100 ps.

Furthermore, the output circuit 230 may determine a unit delay time based on a difference between a number of inverters, included in an electrical path through which the first delay clock DS1 is output, and a number of inverters included in an electrical path through which the second delay clock DS2 is output.

For example, the first delay clock DS1 may be output through the 1-4-th path P14 including eight inverters connected in series, and the second delay clock DS2 may be output through the 2-1-th path P21 including two inverters connected in series. When the first delay clock DS1 and the second delay clock DS2 have a delay time difference corresponding to six inverters therebetween, the output circuit 230 may determine that the unit delay time is 200 ps by dividing 1200 ps, the time difference TD of the two delay clocks DS1 and DS2, by 6.

For example, the output circuit 230 may determine that a unit delay time caused by a single inverter, among a plurality of inverters included in each of the first chain circuit 211 and the second chain circuit 212, is 200 ps.

Referring to the above-described configurations, the test device 110B according to one or more example embodiments may determine the unit delay time using the period the oscillation signal OCS and a result of an XOR operation between and the delay clocks DS1 and DS2 generated by applying different delay times to the clock signal CK.

The unit delay time may be understood as a time corresponding to a delay time caused by a single inverter included in each of the first chain circuit 211 and the second chain circuit 212.

Referring to FIG. 4A, the control logic circuit 210 may control the first multiplexer MUX1 to output an input signal Din to the memory device 120.

In addition, the control logic circuit 210 according to one or more example embodiments may control the first chain circuit 211 to output a third delay clock DS3 to which a third delay time, equal to a third integer multiple of the unit delay time, is applied.

For example, referring to FIG. 4B, the control logic circuit 210 may control the first chain circuit 211 to output the third delay clock DS3 generated by advancing a clock signal CK by a first time T1, which is equal to twice the unit delay time.

According to one or more example embodiments, the second XOR gate XOR2 may perform an XOR operation between the third delay clock DS3 and an input signal Din. For example, the second XOR gate XOR2 may output a third operation signal CS3 as a result of an XORing the third delay clock DS3 and the input signal Din.

For example, the second XOR gate XOR2 may perform an XOR operation between the third delay clock DS3 and the input signal Din based on the memory device 120 outputting an output signal Dout having a high level in response to the third delay clock DS3.

Referring to FIG. 4B, the second XOR gate XOR2 may output a third operation signal CS3 having a waveform maintained at a high level (for example, “1”) from a time a rising edge of the input signal Din occurs to a time a rising edge of the third delay clock DS3 occurs.

In addition, the output circuit 230 may count a number of rising edges of the third output signal OS3.

The AND gate A may output the third output signal OS3, based on a result of an AND operation between the third operation signal CS3 and the oscillation signal OCS.

Referring to FIG. 4B, the third output signal OS3 may have the same waveform as the waveform of the oscillation signal OCS while the third operation signal CS3 is maintained at a high level.

For example, the output circuit 230 may count a number of rising edges of the oscillation signal OCS (or the third output signal OS3) that occur while the third operation signal CS3 is maintained at a high level.

Furthermore, the output circuit 230 may determine a first threshold setup time ST1 based on the number of rising edges of the oscillation signal OCS, which are counted while the third operation signal CS3 is maintained at a high level, and a period of the oscillation signal OCS.

For example, referring to FIG. 4B, the output circuit 230 may determine that four rising edges of the oscillation signal OCS occur while the third operation signal CS3 is maintained at a high level.

In addition, the output circuit 230 may determine that a first threshold setup time ST1 is 400 ps, based on four rising edges of the oscillation signal OCS that occur while the third operation signal CS3 is maintained at a high level and the period of the oscillation signal OCS being 100 ps.

In addition, the control logic circuit 210 may control the first chain circuit 211 to output a fourth delay clock DS4, to which a fourth delay time equal to a fourth integer multiple of the unit delay time is applied, based on the memory device 120 outputting an output signal Dout having a high level in response to the third delay clock DS3.

For example, referring to FIG. 4C, the control logic circuit 210 may control the first chain circuit 211 to output the fourth delay clock DS4 generated by advancing the clock signal CK by a second time T2, which is equal to four times the unit delay time.

Furthermore, the second XOR gate XOR2 may perform an XOR operation between the fourth delay clock DS4 and the input signal Din.

For example, the second XOR gate XOR2 may output a fourth operation signal CS4 as a result of an XORing the fourth delay clock DS4 and the input signal Din.

For example, referring to FIG. 4C, the second XOR gate XOR2 may output the fourth operation signal CS4 having a waveform maintained at a high level (for example, “1”) from a time the rising edge of the input signal Din occurs to a time a rising edge of the fourth delay clock DS4 occurs.

In addition, the output circuit 230 may count a number of rising edges of the fourth output signal OS4.

The AND gate A may output the fourth output signal OS4, based on a result of an AND operation between the fourth operation signal CS4 and the oscillation signal OCS.

Referring FIG. 4C, the fourth output signal OS4 may have the same waveform as the waveform of the oscillation signal OCS while the fourth operation signal CS4 is maintained at a high level.

For example, the output circuit 230 may count a number of rising edges of the oscillation signal OCS (or the fourth output signal OS4) that occur while the fourth operation signal CS4 is maintained at a high level.

Furthermore, the output circuit 230 may determine a second threshold setup time ST2 based on the number of rising edges of the oscillation signal OCS that are counted while the fourth operation signal CS4 is maintained at a high level, and the period of the oscillation signal OCS.

For example, referring to FIG. 4C, the output circuit 230 may determine that three rising edges of the oscillation signal OCS occur while the fourth operation signal CS4 is maintained at a high level.

In addition, the output circuit 230 may determine that a second threshold setup time ST2 is 300 ps, based on four rising edges of the oscillation signal OCS occur while the fourth operation signal CS4 is maintained at a high level, and the period of the oscillation signal OCS being 100 ps.

Referring to FIG. 4B, the memory device 120 may output an output signal Dout having a high-level (for example, “1”) in response to the input signal Din and the third delay clock DS3. The input signal Din and the third delay clock DS3 may be understood to be in a state satisfying the setup time of the memory device 120.

Referring to FIG. 4C, the memory device 120 may output an output signal Dout having a low level (for example, “0”) in response to the input signal Din and the fourth delay clock DS4. The input signal Din and the fourth delay clock DS4 may be understood to be in a setup time violation state that does not satisfy the setup time of the memory device 120.

Accordingly, the test device 110B may determine that the setup time of the memory device 120 has a value between the first threshold setup time ST1 and the second threshold setup time ST2.

For example, the test device 110B (or the control logic circuit 210) may determine that the setup time of the memory device 120 has a value between a time difference between the rising edge of the third delay clock DS3 and the rising edge of the input signal Din (corresponding to the first threshold setup time ST1) and a time difference between the rising edge of the fourth delay clock DS4 and the rising edge of the input signal Din (corresponding to the second threshold setup time ST2).

Referring to the above-described configurations, the test device 110B may determine a unit delay time, caused by an inverter included in each of the chain circuit 211 and 212, using a result of an XOR operation between the delay clocks DS1 and DS2 to which different delay times are applied.

Furthermore, the test device 110B may determine the setup time of the memory device 120 based on the result of the XOR operation between the input signal Din and the delay clocks DS3 and DS4, and the unit delay time.

In an example embodiment, the test device 110B (or the control logic circuit 210) may apply different delay times to the input signal Din to generate a plurality of delayed input signals.

For example, the test device 110B may apply different delay times to the input signal Din such that the rising edge of the input signal Din is delayed by different delay times.

Furthermore, the test device 110B may determine the setup time of the memory device 120 based on a result of an XOR operation between each of a plurality of delayed input signals and the clock signal CK, and the unit delay time.

As a result, the memory system 100B according to one or more example embodiments may improve an accuracy of an operation (or process) of measuring the setup time of the memory device 120.

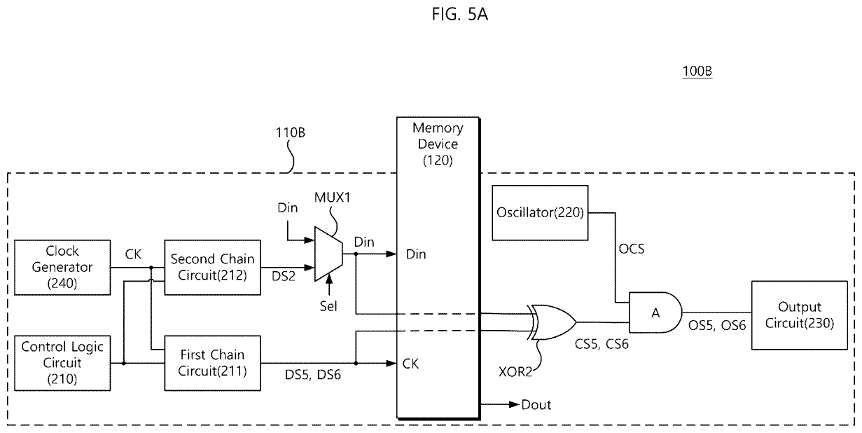

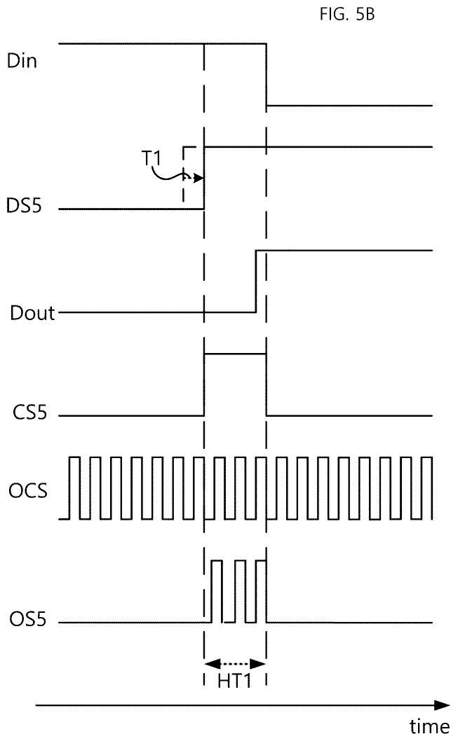

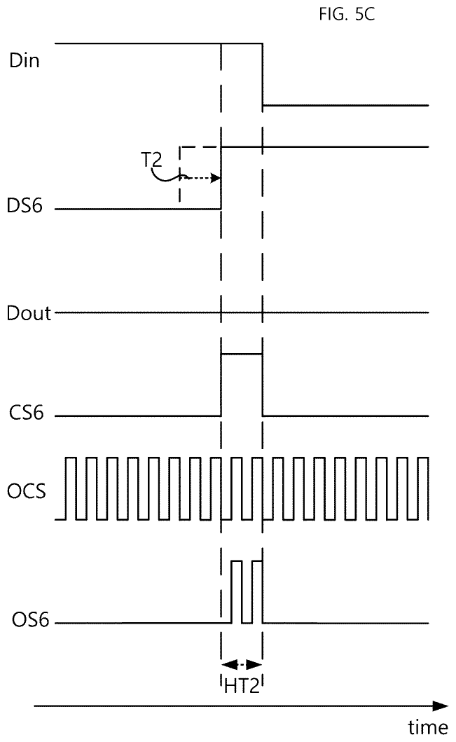

FIG. 5A is a circuit diagram illustrating a configuration in which a test device according to one or more example embodiments outputs a fifth delay clock and a sixth delay clock, to which different delay times are applied, through a first chain circuit. FIG. 5B is a diagram illustrating a configuration in which first threshold hold time is determined through an output circuit when the test device of FIG. 5A outputs a third delay clock through the first chain circuit. FIG. 5C is a diagram illustrating a configuration in which second threshold hold time is determined through the output circuit when the test device of FIG. 5A outputs a fourth delay clock through the first chain circuit.

Referring to FIGS. 5A to 5C, a memory system 100B according to one or more example embodiments may include a test device 110B and a memory device 120.

It will be understood that the memory system 100B illustrated in FIG. 5A may have substantially the same configuration as the memory system 100B illustrated in FIGS. 3A and 4A.

Therefore, the same or substantially the same components may be represented by the same reference numerals, and redundant descriptions are omitted to avoid repetition.

Referring to FIG. 5A, the control logic circuit 210 may control the first multiplexer MUX1 to output the input signal Din to the memory device 120.

In addition, the control logic circuit 210 according to one or more example embodiments may control the first chain circuit 211 to output a fifth delay clock DS5 to which a fifth delay time, equal to a fifth integer multiple of the unit delay time, is applied.

For example, referring to FIG. 5B, the control logic circuit 210 may control the first chain circuit 211 to output a fifth delay clock DS5 obtained by delaying the clock signal CK by a first time T1 equal to twice the unit delay time.

According to one or more example embodiments, a second XOR gate XOR2 may perform an XOR operation between a fifth delay clock DS5 and an input signal Din. For example, a second XOR gate XOR2 may output a fifth operation signal CS5 as a result of XORing the fifth delay clock DS5 and the input signal Din.

For example, the second XOR gate XOR2 may perform an XOR operation between the fifth delay clock DS5 and the input signal Din based on the memory device 120 outputting an output signal Dout having a high level in response to the fifth delay clock DS5.

Referring to FIG. 5B, the second XOR gate XOR2 may output a fifth operation signal CS5 having a waveform maintained at a high level (for example, “1”) from a time a rising edge of the fifth delay clock DS5 occurs to a time a falling edge of the input signal Din occurs.

In addition, the output circuit 230 may count a number of rising edges of a fifth output signal OS5.

An AND gate A may output the fifth output signal OS5, based on a result of an AND operation between the fifth operation signal CS5 and the oscillation signal OCS.

Referring to FIG. 5B, the fifth output signal OS5 may have the same waveform as the waveform of the oscillation signal OCS while the fifth operation signal CS5 is maintained at a high level.

For example, the output circuit 230 may count a number of rising edges of the oscillation signal OCS (or the fifth output signal OS5) that occur while the fifth operation signal CS5 is maintained at a high level.

Furthermore, the output circuit 230 may determine a first threshold hold time HT1 based on the number of rising edges of the oscillation signal OCS that are counted while the fifth operation signal CS5 is maintained at a high level, and a period of the oscillation signal OCS.

For example, referring to FIG. 5B, the output circuit 230 may determine that three rising edge of the oscillation signal OCS occurs while the fifth operation signal CS5 is maintained at a high level.

In addition, the output circuit 230 may determine that the first threshold hold time HT1 is 300 ps based on three rising edges of the oscillation signal OCS that occur while the fifth operation signal CS5 is maintained at a high level, and the period of the oscillation signal OCS being 100 ps.

In addition, the control logic circuit 210 may control the first chain circuit 211 to output a sixth delay clock DS6, to which a sixth delay time equal to a sixth integer multiple of the unit delay time is applied, based on the memory device 120 outputting an output signal Dout having a high level in response to the fifth delay clock DS5.

For example, referring to FIG. 5C, the control logic circuit 210 may control the first chain circuit 211 to output a sixth delay clock DS6 obtained by delaying the clock signal CK by a second time T2 equal to four times the unit delay time.

Furthermore, the second XOR gate XOR2 may perform an XOR operation between the sixth delay clock DS6 and the input signal Din.

For example, the second XOR gate XOR2 may output a sixth operation signal CS6 as a result of XORing the sixth delay clock DS6 and the input signal Din.

For example, referring to FIG. 5C, the second XOR gate XOR2 may output a sixth operation signal CS6 having a waveform maintained at a high level (for example, “1”) from a time a rising edge of the sixth delay clock DS6 occurs to a time a falling edge of the input signal Din occurs.

In addition, the output circuit 230 may count a number of rising edges of a sixth output signal OS6.

The AND gate A may output the sixth output signal OS6, a result of an AND operation between the sixth operation signal CS6 and the oscillation signal OCS.

Referring to FIG. 5C, the sixth output signal OS6 may have the same waveform as the waveform of the oscillation signal OCS while the sixth operation signal CS6 is maintained at a high level.

For example, the output circuit 230 may count a number of rising edges of the oscillation signal OCS (or the sixth output signal OS6) that occur while the sixth operation signal CS6 is maintained at a high level.

Furthermore, the output circuit 230 may determine a second threshold hold time HT2 based on the number of rising edges of the oscillation signal OCS that are counted while the sixth operation signal CS6 is maintained at a high level, and the period of the oscillation signal OCS.

For example, referring to FIG. 5C, the output circuit 230 may determine that two rising edges of the oscillation signal OCS occur while the sixth operation signal CS6 is maintained at a high level.

In addition, the output circuit 230 may determine that the second threshold hold time HT2 is 200 ps based on the two rising edges of the oscillation signal OCS that occur while the sixth operation signal CS6 is maintained at a high level, and the period of the oscillation signal OCS being 100 ps.

Referring to FIG. 5B, the memory device 120 may output the output signal Dout having a high level (for example, “1”) in response to the input signal Din and the fifth delay clock DS5. It will be understood that he input signal Din and the fifth delay clock DS5 are in a state satisfying the hold time of the memory device 120.

Referring to FIG. 5C, the memory device 120 may output the output signal Dout having a low level (for example, “0”) in response to the input signal Din and the sixth delay clock DS6. It will be understood that the input signal Din and the sixth delay clock DS6 are in a hold time violation state that do not satisfy the hold time of the memory device 120.

Accordingly, the test device 110B may determine that the hold time of the memory device 120 has a value between the first threshold hold time HT1 and the second threshold hold time HT2.

For example, the test device 110B (or the control logic circuit 210) may determine that the hold time of the memory device 120 has a value between a time difference between the rising edge of the fifth delay clock DS5 and the falling edge of the input signal Din (corresponding to the first threshold hold time HT1) and a time difference between the rising edge of the sixth delay clock DS6 and the falling edge of the input signal Din (corresponding to the second threshold hold time HT2).

Referring to the above-described configurations, the test device 110B according to one or more example embodiments may determine the hold time of the memory device 120 based on a result of the XOR operation between the input signal Din and the delay clocks DS5 and DS6, and a unit delay time.

According to one or more example embodiments, the test device 110B (or the control logic circuit 210) may apply different delay times to the input signal Din to generate a plurality of delayed input signals.

Furthermore, the test device 110B may determine the hold time of the memory device 120 based on a result of an XOR operation between each of the plurality of delayed input signals and the clock signal CK, and the unit delay time.

As a result, the memory system 100B according to one or more example embodiments may improve the accuracy of an operation (or process) of measuring the hold time of the memory device 120.

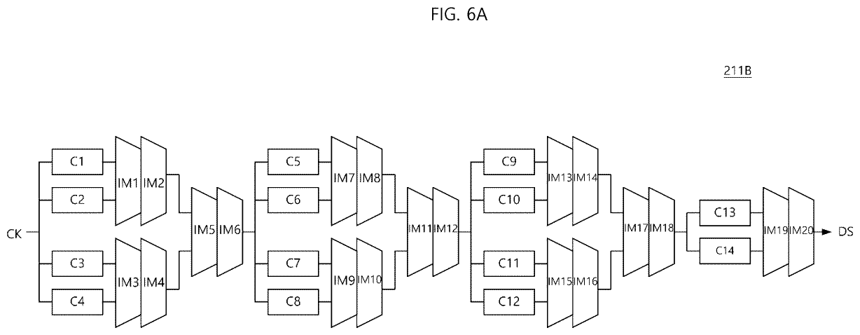

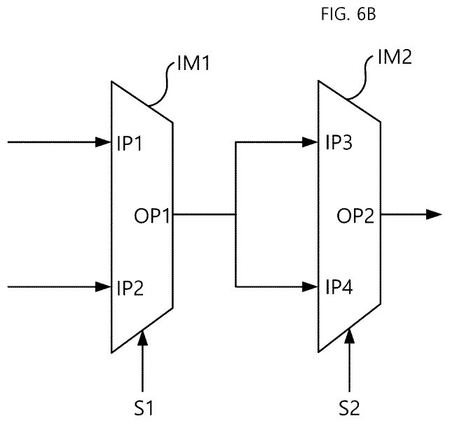

FIG. 6A is a circuit diagram illustrating a configuration of the first chain circuit according to one or more example embodiments. FIG. 6B is a circuit diagram illustrating a configuration of a first internal multiplexer and the second internal multiplexer of the first chain circuit of FIG. 6A.

Referring to FIG. 6A, a first chain circuit 211B according to one or more example embodiments may include delay elements C1 to C14, each including at least one inverter.

According to one or more example embodiments, each of the delay elements C1 to C14 may include at least two inverters connected in series. For example, a first delay element C1 may include two inverters connected in series. For example, a fourth delay element C4 may include eight inverters connected in series.

In addition, the first chain circuit 211B may include a plurality of internal multiplexers IM1 to IM20 electrically connected to the delay elements C1 to C14.

For example, the first chain circuit 211B may include a first internal multiplexer IM1 electrically connected to the first delay element C1 and the second delay element C2. In addition, the first chain circuit 211B may include a second internal multiplexer IM2 electrically connected to the first internal multiplexer IM1.

According to one or more example embodiments, the control logic circuit 210 may control the plurality of internal multiplexers IM1 to IM20, included in the first chain circuit 211B, to control a delay time applied to a clock signal CK.

For example, the control logic circuit 210 may control the plurality of internal multiplexers IM1 to IM20 such that the clock signal CK is delayed and output through at least a portion of the plurality of delay elements C1 to C14 included in the first chain circuit 211B.

Referring to FIG. 6B, the first internal multiplexer IM1 may include a first input port IP1, a second input port IP2, and a first output port OP1.

The second internal multiplexer IM2 may include a third input port IP3, a fourth input port IP4, and a second output port OP2. The second internal multiplexer IM2 may receive a signal, output from the first output port OP1, through the third input port IP3 and the fourth input port IP4.

According to one or more example embodiments, the first internal multiplexer IM1 and the second internal multiplexer IM2 may be implemented with substantially the same structure. Furthermore, the multiple internal multiplexers IM1 to IM20 may be implemented with substantially the same structure.

For example, an electrical distance between the third input port IP3 and the second output port OP2 may be the same as or similar to an electrical distance between the first input port IP1 and the first output port OP1.

In addition, an electrical distance between the fourth input port IP4 and the second output port OP2 may be the same as or similar to an electrical distance between the second input port IP2 and the first output port OP1.

In addition, the control logic circuit 210 according to one or more example embodiments may control the first internal multiplexer IM1 and the second internal multiplexer IM2 such that a signal, input to the first internal multiplexer IM1, is output through paths having different electrical distances within the first internal multiplexer IM1 and the second internal multiplexer IM2.

For example, the control logic circuit 210 may control the first internal multiplexer IM1 through a first signal S1 to output a signal input to the first input port IP1, while controlling the second internal multiplexer IM2 through a second signal S2 to output the signal input to the fourth input port IP4.

For example, the control logic circuit 210 may control the second internal multiplexer IM2 to output a signal input to the third input port IP3 when controlling the first internal multiplexer IM1 to output a signal input to the second input port IP2.

For example, the control logic circuit 210 may control electrically connected internal multiplexers (for example, IM1 and IM2) to output signals input to input ports, which do not correspond to each other, at the internal multiplexers (for example, IM1 and IM2).

In addition, the second chain circuit according to one or more example embodiments (for example, the second chain circuit 212 of FIG. 3A) may have substantially the same structure as the first chain circuit 211B.

Referring to the above-described configurations, the control logic circuit 210 (or the memory system 100) according to one or more example embodiments may control electrically connected internal multiplexers such that a signal, output from each of the delay elements C1 to C14, is output through paths having different electrical distances.

As a result, the memory system 100 according to one or more example embodiments may significantly reduce an error caused by mismatch between internal paths of each of the internal multiplexers IM1 to IM20 when controlling a delay of the clock signal CK through the chain circuits 211B and 212.

For example, the memory system 100 according to one or more example embodiments may control the delay of the clock signal CK through the above-described configurations to improve the accuracy of an operation (or process) of measuring timing specifications of the memory device 120.

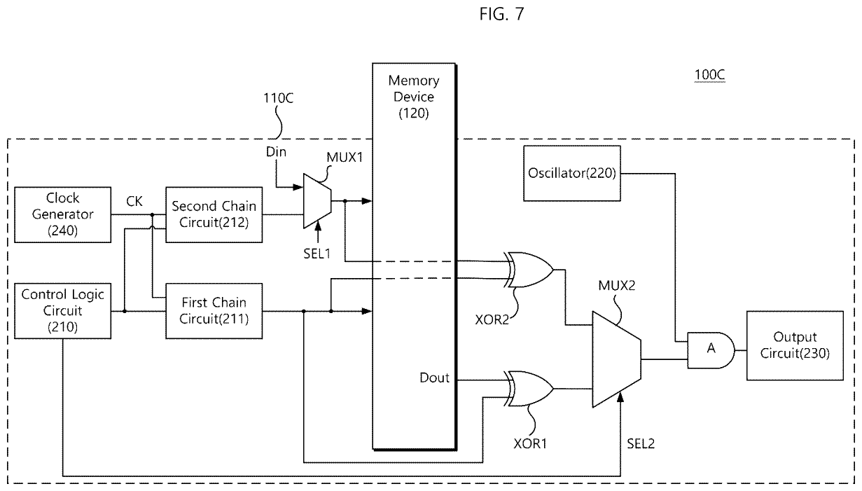

FIG. 7 is a circuit diagram illustrating a memory system including a test device further including a second multiplexer according to one or more example embodiments.

Referring to FIG. 7, a memory system 100C according to one or more example embodiments may include a test device 110C and a memory device 120. The test device 110C may include a first chain circuit 211, a second chain circuit 212, a control logic circuit 210, a first multiplexer MUX1, a second multiplexer MUX2, a first XOR gate XOR1, a second XOR gate XOR2, an oscillator 220, an AND gate A, and an output circuit 230.

The memory system 100C illustrated in FIG. 7 may be understood as an example of the memory system 100 illustrated in FIG. 1. Therefore, the same or substantially the same components may be represented by the same reference numerals, and redundant descriptions are omitted to avoid repetition.

Referring to FIG. 7, the test device 110C according to one or more example embodiments may include the second multiplexer MUX2 electrically connected to the first XOR gate XOR1 and the second XOR gate XOR2.

For example, the test device 110C may include the second multiplexer MUX2 electrically connected between the first XOR gate XOR1 and the second XOR gate XOR2, and the AND gate A.

The second multiplexer MUX2 according to one or more example embodiments may selectively output a signal, output from the first XOR gate XOR1, and a signal, output from the second XOR gate XOR2, in response to a second select signal SEL2.

According to one or more example embodiments, the control logic circuit 210 may control the second multiplexer MUX2 through the second select signal SEL2 to selectively output the signal, output from the first XOR gate XOR1, and the signal, output from the second XOR gate XOR2, to the AND gate A through the second multiplexer MUX2.

For example, the control logic circuit 210 may transmit the signal, output from the first XOR gate XOR1, to the AND gate A through the second multiplexer MUX2 such that the output circuit 230 determines an access time of the memory device 120 based on the signal output from the first XOR gate XOR1.

For example, the control logic circuit 210 may transmit the signal, output from the second XOR gate XOR2, to the AND gate A through the second multiplexer MUX2 such that the output circuit 230 determines a setup time and/or a hold time of the memory device 120 based on the signal output from the second XOR gate XOR2.

Referring to the above-described configurations, the test device 110C according to one or more example embodiments may measure the access time of the memory device 120, the setup time, and/or the hold time of the memory device 120 based on the second select signal SEL2.

For example, the test device 110C according to one or more example embodiments may determine the timing specifications (access time, setup time, and/or hold time) of the memory device 120 using a minimum circuit configuration.

Accordingly, the memory system 100C may significantly reduce the configuration and/or area of a circuit for measuring the timing specifications of the memory device 120.

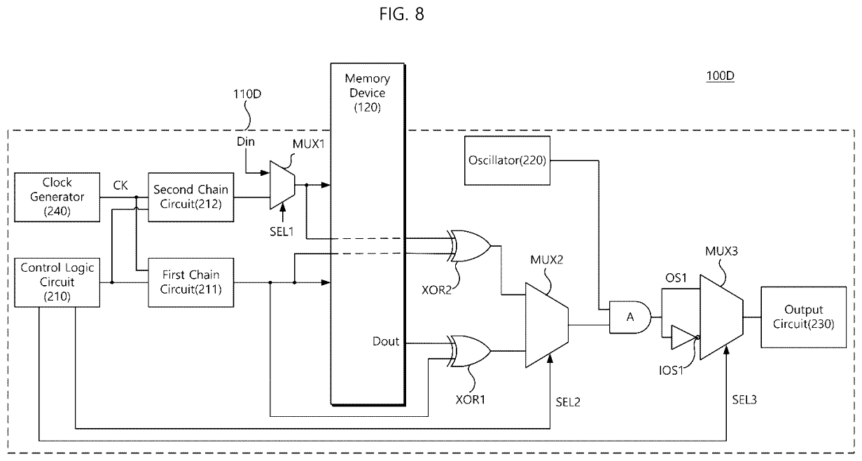

FIG. 8 is a circuit diagram illustrating a memory system including a test device further including a third multiplexer according to one or more example embodiments.

Referring to FIG. 8, a memory system 100D according to one or more example embodiments may include a test device 110D and a memory device 120. In addition, the test device 110D may include a first chain circuit 211, a second chain circuit 212, a control logic circuit 210, a first multiplexer MUX1, a second multiplexer MUX2, a third multiplexer MUX3, a first XOR gate XOR1, a second XOR gate XOR2, an oscillator 220, an AND gate A, and an output circuit 230.

The memory system 100D illustrated in FIG. 8 may be understood as an example of the memory system 100 illustrated in FIG. 1. Therefore, the same or substantially the same components may be represented by the same reference numerals, and redundant descriptions are omitted to avoid repetition.

Referring to FIG. 8, the test device 110D according to one or more example embodiments may include the third multiplexer MUX3 electrically connected between the AND gate A and the output circuit 230.

For example, the third multiplexer MUX3 may selectively output a first output signal OS1 and a first inverted signal IOS1 output from the AND gate A in response to a third select signal SEL3.

The first inverted signal IOS1 may be understood as a signal obtained by inverting the first output signal OS1 through an inverter.

The control logic circuit 210 according to one or more example embodiments may control the third multiplexer MUX3 through the third select signal SEL3 to selectively output the first output signal OS1 and the first inverted signal IOS1 to the output circuit 230.

For example, the control logic circuit 210 may control the third multiplexer MUX3 through the third select signal SEL3 to alternately output the first output signal OS1 and the first inverted signal IOS1 to the output circuit 230.

Furthermore, the output circuit 230 may count a number of rising edges of a first average signal corresponding to an average of the first output signal OS1, output through the third multiplexer MUX3, and the first inverted signal IOS1.

Referring to the above-described configurations, the test device 110D (or the output circuit 230) according to one or more example embodiments may count the number of rising edges based on a signal corresponding to the average of the signal output from the AND gate A and the signal obtained by inverting the output signal.

Furthermore, the output circuit 230 may determine the timing specifications of the memory device 120 based on the number of the counted rising edges.

As a result, the memory system 100D according to one or more example embodiments may significantly reduce the impact of errors, occurring in a time domain adjacent to an edge of the first output signal OS1, due to internal components of the test device 110D.

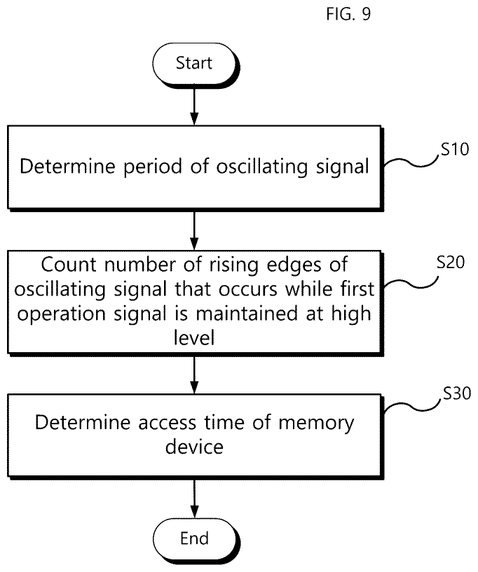

FIG. 9 is a flowchart illustrating a test method for determining an access time of a memory device according to one or more example embodiments.

Referring to FIG. 9, the test device 110 (or the memory system 100) according to one or more example embodiments may determine an access time of the memory device 120 based on a result of an XOR operation between a clock signal CK and an output signal Dout.

The output signal Dout may be referred to as a data signal output from the memory device 120 in response to an input signal Din and the clock signal CK input to the memory device 120.

In operation S10, the test device 110 according to one or more example embodiments may determine a period of an oscillation signal OCS.

For example, the test device 110 (or the output circuit 230) may determine a period of the oscillation signal OCS by dividing the oscillation signal OCS output from the oscillator 220.

In operation S20, the test device 110 according to one or more example embodiments may count the number of rising edges of the oscillation signal OCS that occur while the first operation signal CS1 is maintained at a high level.

The test device 110 may output a first operation signal CS1 as a result of an XOR operation of the clock signal CK and the output signal Dout.

In addition, the test device 110 may perform an AND operation on the first operation signal CS1 and the oscillation signal OCS.

Furthermore, the test device 110 (or the output circuit 230) may count the number of rising edges of the first output signal OS1 output as a result of the AND operation of the first operation signal CS1 and the oscillation signal OCS.

In operation S30, the test device 110 according to one or more example embodiments may determine the access time of the memory device 120.

For example, the test device 110 may determine the access time of the memory device 120 based on the number of rising edges of the oscillation signal OCS, counted while the first operation signal CS1 is maintained at a high level, and the period of the oscillation signal OCS.

For example, the test device 110 may determine the access time of the memory device 120 to be 500 ps based on five rising edges of the oscillation signal OCS that occur while the first operation signal CS1 is maintained at a high level, and the period of the oscillation signal OCS being 100 ps.

The access time may be understood to correspond to the time taken for the memory device 120 to output the output signal Dout in response to the clock signal CK in a state in which the input signal Din is input to the memory device 120.

For example, the output circuit 230 may determine that the time taken for the memory device 120 to output a rising edge of the output signal Dout in response to the rising edge of the clock signal, in the state in which the input signal Din is input to the memory device 120, is 500 ps.

Referring to the above-described configurations, the test device 110 according to one or more example embodiments may determine the period of the oscillation signal OCS by dividing the oscillation signal OCS.

In addition, the test device 110 may determine the access time of the memory device 120 using the determined period and the result of the XOR operation between the clock signal CK and the output signal Dout.

As a result, the memory system 100 according to one or more example embodiments may improve the accuracy of the operation (or process) of measuring the access time of the memory device 120.

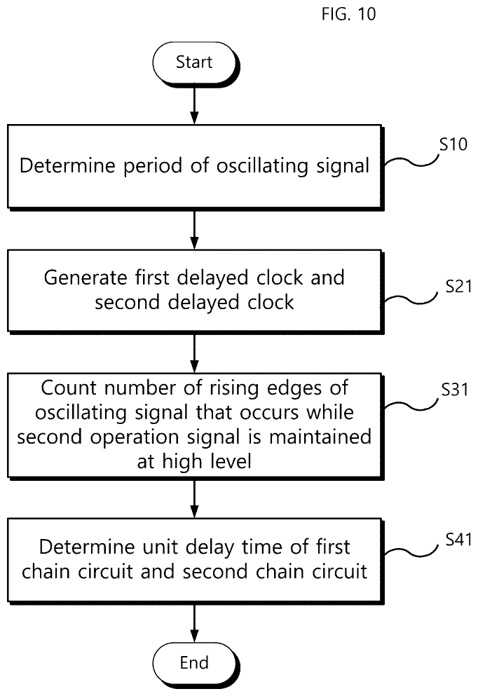

FIG. 10 is a flowchart illustrating a method for determining a unit delay time of a first chain circuit and a second chain circuit included in a test device according to one or more example embodiments.

Referring to FIG. 10, the test device 110 according to one or more example embodiments may determine a unit delay time caused by one of the plurality of inverters included in each of the first chain circuit 211 and the second chain circuit 212.

In operation S10, the test device 110 according to one or more example embodiments may determine the period of the oscillation signal OCS.

For example, the test device 110 (or the output circuit 230) may determine the period of the oscillation signal OCS by dividing the oscillation signal OCS output from the oscillator 220.

In operation S21, the test device 110 according to one or more example embodiments may generate a first delayed clock DS1 and a second delayed clock DS2.

For example, the test device 110 may generate a first delayed clock DS1 and a second delayed clock DS2, in which different delay times are applied to the clock signal CK, by controlling the first chain circuit 211 and the second chain circuit 212.

For example, the test device 110 may generate a first delayed clock DS1, to which a first delay time equal to a first integer multiple of the unit delay time is applied, by controlling the first chain circuit 211. In addition, the test device 110 may generate a second delayed clock DS2, to which a second delay time equal to a second integer multiple of the unit delay time is applied, by controlling the second chain circuit 212. The second integer may be smaller than the first integer, but example embodiments are not limited thereto.

In operation S31, the test device 110 according to one or more example embodiments may count the number of rising edges of the oscillation signal OCS that occur while the second operation signal CS2 is maintained at a high level.

The test device 110 according to one or more example embodiments may output a second operation signal CS2 as a result of an XOR operation on the first delayed clock DS1 and the second delayed clock DS2.

In addition, the test device 110 may perform an AND operation on the second operation signal CS2 and the oscillation signal OCS.

Furthermore, the test device 110 (or the output circuit 230) may count the number of rising edges of the second output signal OS2 output as a result of the AND operation on the second operation signal CS2 and the oscillation signal OCS.

In addition, the test device 110 may determine that a time difference TD between the first delayed clock DS1 and the second delayed clock DS2 is 1200 ps, based on 12 rising edges of the oscillation signal OCS that occur while the second operation signal CS2 is maintained at a high level, and the period of the oscillation signal OCS being 100 ps.

Furthermore, the test device 110 may determine a unit delay time based on a difference between the number of inverters, included in an electrical path through which the first delayed clock DS1 is output, and the number of inverters included in an electrical path through which the second delayed clock DS2 is output.

For example, the test device 110 may determine the unit delay time to be 200 ps by dividing 1200 ps, the time difference TD between the first and second delayed clocks DS1 and DS2, by 6 when the two delayed clock DS1 and DS2 have a delay time difference corresponding to six inverters therebetween.

For example, the test device 110 may determine that the unit delay time caused by one of the plurality of inverters included in each of the first chain circuit 211 and the second chain circuit 212 is 200 ps.

Referring to the above-described configurations, the test device 110 according to one or more example embodiments may determine the unit delay time using the result of the XOR operation between delayed clocks DS1 and DS2, to which different delay times are applied to the clock signal CK, and the period of the oscillation signal OCS.

As a result, the memory system 100 according to one or more example embodiments may accurately determine the unit delay time of a circuit, applying a delay to the clock signal CK, to determine timing specifications of the memory device 120.

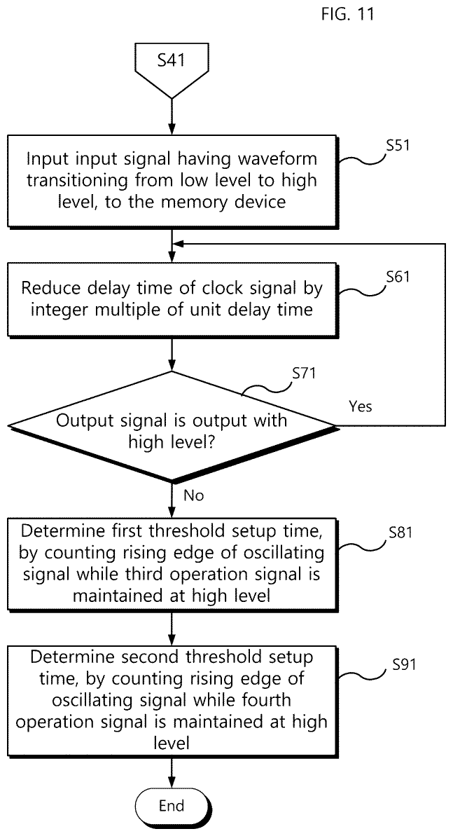

FIG. 11 is a flowchart illustrating a test method for determining a setup time of a memory device based on unit delay time according to one or more example embodiments.

Referring to FIGS. 10 and 11, the test device 110 according to one or more example embodiments may determine the setup time of the memory device 120 based on the unit delay time and the result of the XOR operation between the delayed clock and the input signal.

In operation S51, the test device 110 according to one or more example embodiments may input an input signal Din, having a waveform transitioning from a low level to a high level, to the memory device 120.

For example, the test device 110 may set a value of the output signal Dout, output from the memory device 120, to “0” and then input the input signal Din, having the waveform transitioning from a low level to a high level, to the memory device 120.

In operation S61, the test device 110 according to one or more example embodiments may reduce the delay time of the clock signal CK by an integer multiple of the unit delay time.

For example, the test device 110 may control the first chain circuit 211 to output a delayed clock, to which a delay time equal to an integer multiple of the unit delay time is applied, to the clock signal CK.

For example, the test device 110 may control the first chain circuit 211 to output a third delayed clock DS3, to which a third delay time equal to an integer multiple of the unit delay time is applied, to the clock signal CK. For example, the third integer may be referred to as “2,” but example embodiments are not limited thereto.

In operation S71, the test device 110 according to one or more example embodiments may determine whether the output signal Dout is output with a high level.

For example, the test device 110 may determine whether the memory device 120 outputs the output signal Dout having a high level in response to the rising edges of the input signal Din and the third delayed clock DS3.

For example, when the memory device 120 outputs the output signal Dout having a high level (for example, “1”) in response to the input signal Din and the third delayed clock DS3, the input signal Din and the third delayed clock DS3 may be understood to be in a state satisfying the setup time of the memory device 120.

Furthermore, the test device 110 may output a fourth delayed clock DS4, to which a fourth delay time equal to an integer multiple of the unit delay time is applied, to the clock signal CK based on the memory device 120 outputting the output signal Dout having a high level in response to the rising edge of the third delayed clock DS3. For example, the fourth integer may be referred to as “4,” but example embodiments are not limited thereto.

In addition, for example, when the memory device 120 outputs the output signal Dout having a low level (for example, “0”) in response to the input signal Din and the fourth delayed clock DS4, the input signal Din and the fourth delayed clock DS4 may be understood to be in a setup time violation state that does not satisfy the setup time of the memory device 120.

In operation S81, the test device 110 may determine a first threshold setup time ST1 by counting the number of rising edges of the oscillation signal OCS that occur while a third operation signal CS3 is maintained at a high level. The third operation signal CS3 may be referred to as a result of an XOR operation between the third delayed clock DS3 and the input signal Din.

In operation S91, the test device 110 may determine a second threshold setup time ST2 by counting the number of rising edges of the oscillation signal OCS that occur while a fourth operation signal CS4 is maintained at a high level. The fourth operation signal CS4 may be referred to as a result of an XOR operation between the fourth delayed clock DS4 and the input signal Din.

According to one or more example embodiments, the setup time of the memory device 120 may have a value between the first threshold setup time ST1 and the second threshold setup time ST2. For example, the test device 110 may determine that the setup time of the memory device 120 has a value between the first threshold setup time ST1 and the second threshold setup time ST2.

Referring to the above-described configurations, the test device 110 may determine the setup time of the memory device 120 based on the result of the XOR operation between the input signal Din and the delayed clocks DS3 and DS4, and the unit delay time.

As a result, the memory system 100 according to one or more example embodiments may improve the accuracy of the operation (or process) of measuring the setup time of the memory device 120.

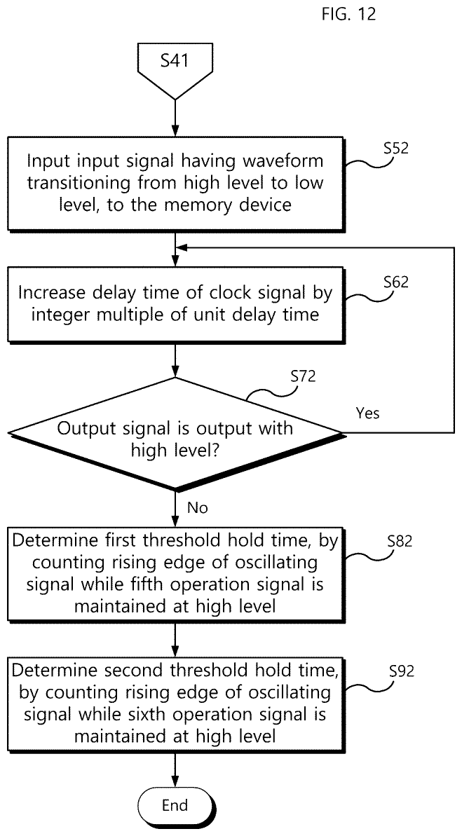

FIG. 12 is a flowchart illustrating a test method for determining a hold time of a memory device based on the unit delay time according to one or more example embodiments.

Referring to FIGS. 10 and 12, the test device 110 according to one or more example embodiments may determine a hold time of the memory device 120 based on a unit delay time and a result of an XOR operation between a delayed clock and an input signal.

In operation S52, the test device 110 according to one or more example embodiments may input an input signal Din, having a waveform transitioning from a high level to a low level, to the memory device 120.

For example, the test device 110 may set a value of the output signal Dout, output from the memory device 120, to “0” and then input an input signal Din, having a waveform transitioning from a high level to a low level, to the memory device 120.

In operation S62, the test device 110 according to one or more example embodiments may increase the delay time of the clock signal CK by an integer multiple of the unit delay time.

For example, the test device 110 may control the first chain circuit 211 to output a delayed clock, to which a delay time equal to an integer multiple of the unit delay time is applied, to the clock signal CK.

For example, the test device 110 may control the first chain circuit 211 to output a fifth delayed clock DS5, to which a fifth delay time equal to an integer multiple of the unit delay time is applied, to the clock signal CK.

In operation S72, the test device 110 according to one or more example embodiments may determine whether the output signal Dout is output with a high level.

For example, the test device 110 may determine whether the memory device 120 outputs the output signal Dout having a high level in response to the rising edge of the input signal Din and the fifth delayed clock DS5.

For example, when the memory device 120 outputs the output signal Dout having a high level (for example, “1”) in response to the input signal Din and a fifth delayed clock DS5, the input signal Din and the fifth delayed clock DS5 may be understood to be in a state satisfying the hold time of the memory device 120.

Furthermore, the test device 110 may output a sixth delayed clock DS6, to which a sixth delay time equal to an integer multiple of the unit delay time is applied, to the clock signal CK based on the memory device 120 outputting the output signal Dout having a high level in response to the rising edge of the fifth delayed clock DS5.

In addition, for example, when the memory device 120 outputs the output signal Dout having a low level (for example, “0”) in response to the input signal Din and a sixth delayed clock DS6, the input signal Din and the sixth delayed clock DS6 may be understood to be in a hold time violation state that does not satisfy the hold time of the memory device 120.

In operation S82, the test device 110 may determine a first threshold hold time HT1 by counting the number of rising edges of the oscillation signal OCS that occur while a fifth operation signal CS5 is maintained at a high level. The fifth operation signal CS5 may be referred to as a result of an XOR operation between the fifth delayed clock DS5 and the input signal Din.

In operation S92, the test device 110 may determine a second threshold hold time HT2 by counting the number of rising edges of the oscillation signal OCS that occur while a sixth operation signal CS6 is maintained at a high level. The sixth operation signal CS6 may be referred to as a result of an XOR operation between the sixth delayed clock DS6 and the input signal Din.

According to one or more example embodiments, the hold time of the memory device 120 may have a value between the first threshold hold time HT1 and the second threshold hold time HT2. For example, the test device 110 may determine that the hold time of the memory device 120 has a value between the first threshold hold time HT1 and the second threshold hold time HT2.

Referring to the above-described configurations, the test device 110 may determine the hold time of the memory device 120 based on the result of the XOR operation between the input signal Din and the delayed clocks DS5 and DS6, and the unit delay time.

As a result, the memory system 100 according to one or more example embodiments may improve the accuracy of an operation (or process) of measuring the hold time of the memory device 120.

As described above, the test device 110 according to one or more example embodiments may measure the access time of the memory device 120 using the result of the XOR operation between the period of the oscillation signal OCS and the clock signal CK, and the output signal Dout.

As a result, the memory system 100 according to one or more example embodiments may improve the accuracy of the operation (or process) of measuring the access time of the memory device 120.

In addition, the test device 110 according to one or more example embodiments may determine the unit delay time caused by each inverter included in each of the chain circuits 211 and 212 using the result of the XOR operation between the delayed clocks DS1 and DS2 to which different delay times are applied.

Furthermore, the test device 110 may determine the setup time of the memory device 120 based on the result of the XOR operation between the input signal Din and the delayed clocks DS3 and DS4, and the unit delay time.

As a result, the memory system 100 according to one or more example embodiments may improve the accuracy of the operation (or process) of measuring the setup time of the memory device 120.

In addition, the test device 110 according to one or more example embodiments may determine the hold time of the memory device 120 based on the result of the XOR operation between the input signal Din and the delayed clocks DS5 and DS6, and the unit delay time.

As a result, the memory system 100 according to one or more example embodiments may improve the accuracy of the operation (or process) of measuring the hold time of the memory device 120.

As set forth above, a test device according to example embodiments may improve the accuracy of an operation of measuring timing specifications of a memory device.

While example embodiments have been shown and described above, it will be apparent to those skilled in the art that modifications and variations could be made without departing from the scope of the disclosure as defined by the appended claims and their equivalents.

What is claimed is:

1. A test device for a memory device, the test device comprising:
a first exclusive OR (XOR) gate configured to output a first operation signal by performing an XOR operation between a clock signal and an output signal output from the memory device;
an oscillator configured to output an oscillation signal; and
an output circuit configured to determine a period of the oscillation signal,
wherein the output circuit is configured to:
count a number of rising edges of the oscillation signal while the first operation signal is maintained at a high level; and
determine an access time of the memory device based on the counted number of the rising edges, and a period of the oscillation signal.

2. The test device of claim 1, further comprising:
a first chain circuit and a second chain circuit, each being configured to receive the clock signal and each comprising a plurality of inverters; and
a control logic circuit connected to the first chain circuit and the second chain circuit,
wherein the control logic circuit is configured to control the first chain circuit and the second chain circuit such that the first chain circuit and the second chain circuit output delayed clocks to which delay times equal to different integer multiples of a unit delay time are respectively applied, and
wherein the unit delay time corresponds to a time delayed by one of the plurality of inverters.

3. The test device of claim 2, further comprising:
a first multiplexer configured to output either one of a signal output from the second chain circuit and an input signal input to the memory device, based on a first select signal; and
a second XOR gate configured to output a second operation signal by performing an XOR operation between a signal output from the first multiplexer and a signal output from the first chain circuit,
wherein the control logic circuit is further configured to:
control the first chain circuit to output a first delayed clock to which a first delay time equal to a first integer multiple of the unit delay time is applied; and
control the second chain circuit and the first multiplexer to output a second delayed clock to which a second delay time equal to a second integer multiple of the unit delay time is applied, and
wherein the output circuit is further configured to determine the unit delay time by counting a number of rising edges of the oscillation signal that occur while the second operation signal is maintained at a high level.

4. The test device of claim 3, wherein the control logic circuit, in a state in which the input signal transitions from a low level to a high level, is configured to:
control the first chain circuit to output a third delayed clock to which a third delay time equal to a third integer multiple of the unit delay time is applied;
based on the output signal having a high level being output from the memory device in response to a rising edge of the third delayed clock, control the first chain circuit to output a fourth delayed clock, to which a fourth delay time equal to a fourth integer multiple of the unit delay time is applied, wherein the output signal having a low level is output in response to the fourth delay time; and
determine a setup time of the memory device based on the unit delay time, the third delay time, and the fourth delay time.

5. The test device of claim 4, wherein the output circuit is further configured to, in determining the setup time:
determine a first threshold setup time by counting a number of rising edges of the oscillation signal that occur while a third operation signal, which is a result of an XOR operation between the third delayed clock and the input signal, is maintained at a high level; determine a second threshold setup time by counting a number of rising edges of the oscillation signal that occur while a fourth operation signal, which is a result of an XOR operation between the fourth delayed clock and the input signal, is maintained at a high level; and
determine the setup time to have a value between the first threshold setup time and the second threshold setup time.

6. The test device of claim 3, wherein the control logic circuit, in a state in which the input signal transitions from a high level to a low level, is configured to:
control the first chain circuit to output a fifth delayed clock to which a fifth delay time equal to a fifth integer multiple of the unit delay time is applied;
based on the output signal having a high level being output from the memory device in response to the fifth delayed clock, control the first chain circuit to output a sixth delayed clock, to which a sixth delay time equal to a sixth integer multiple of the unit delay time is applied, wherein the output signal having a low level is output in response to the sixth delayed clock; and
determine a hold time of the memory device based on the unit delay time, the fifth integer multiple, and the sixth integer multiple.

7. The test device of claim 6, wherein the output circuit is configured to, in determining the hold time:
determine a first threshold hold time by counting a number of rising edges of the oscillation signal that occur while a fifth operation signal, which is a result of an XOR operation between the fifth delayed clock and the input signal, is maintained at a high level; determine a second threshold hold time by counting a number of rising edges of the oscillation signal that occur while a sixth operation signal, which is a result of an XOR operation between the sixth delayed clock and the input signal, is maintained at a high level, and
determine the hold time to have a value between the first threshold hold time and the second threshold hold time.

8. The test device of claim 3, further comprising:
a second multiplexer electrically connected to the first XOR gate and the second XOR gate; and
an AND gate electrically connected between the second multiplexer and the oscillator, and the output circuit,
wherein the output circuit is further configured to count a number of rising edges output through the AND gate while a signal, output from the second multiplexer, of the oscillation signal is maintained at a high level.

9. The test device of claim 8, further comprising:
a third multiplexer configured to receive a first output signal output from the AND gate and a first inverted version of the first output signal,
wherein the output circuit is configured to count a number of rising edges of a first average signal corresponding to an average of the first output signal output from the third multiplexer and the first inverted version.

10. The test device of claim 2, wherein the first chain circuit comprises:
a first internal multiplexer electrically connected to at least a portion of the plurality of inverters and comprising a first input port, a second input port, and a first output port; and
a second internal multiplexer comprising a third input port and a fourth input port, through which a signal output from the first output port is received, and a second output port,
wherein an electrical distance between the third input port and the second output port is the same as an electrical distance between the first input port and the first output port,
wherein an electrical distance between the fourth input port and the second output port is the same as an electrical distance between the second input port and the first output port, and
wherein the control logic circuit is configured to control the first internal multiplexer and the second internal multiplexer to output a signal, input to the first internal multiplexer, to the second output port through a path having different electrical distances in the first internal multiplexer and the second internal multiplexer.

11. A test method for a memory device, the test method comprising:
determining a period of an oscillation signal, output from an oscillator;
counting a number of rising edges of the oscillation signal that occur while a first operation signal, which is a result of an exclusive OR (XOR) operation between a clock signal and an output signal output from the memory device, is maintained at a high level; and
determining an access time of the memory device based on the counted number of the rising edges, and the period of the oscillation signal.

12. The test method of claim 11, comprising:
generating a first delayed clock, in which a first delay time equal to a first integer multiple of a unit delay time is applied to the clock signal, and a second delayed clock in which a second delay time equal to a second integer multiple of the unit delay time is applied to the clock signal;
counting a number of rising edges of the oscillation signal that occur while a second operation signal, which is a result of an XOR operation between the first delayed clock and the second delayed clock, is maintained at a high level; and
determining the unit delay time based on the number of the rising edges of the oscillation signal counted while the second operation signal is maintained at the high level, and the period of the oscillation signal.

13. The test method of claim 12, further comprising:
inputting an input signal, which transitions from a low level to a high level, to the memory device;
inputting a third delayed clock, to which a third delay time equal to a third integer multiple of the unit delay time is applied, to the memory device;
based on the output signal having a high level being output from the memory device in response to a rising edge of the third delayed clock, inputting a fourth delayed clock, to which a fourth delay time equal to a fourth integer multiple of the unit delay time is applied, to the memory device, wherein the output signal having a low level is output in response to the fourth delayed clock; and
determining a setup time of the memory device based on the unit delay time, the third delay time, and the fourth delay time.

14. The test method of claim 13, wherein the determining the setup time comprises:
determining a first threshold setup time by counting a number of rising edges of the oscillation signal that occur while a third operation signal, which is a result of an XOR operation between the third delayed clock and the input signal, is maintained at a high level; determining a second threshold setup time by counting a number of rising edges of the oscillation signal that occur while a fourth operation signal, which is a result of an XOR operation between the fourth delayed clock and the input signal, is maintained at a high level,
determining the setup time to have a value between the first threshold setup time and the second threshold setup time.

15. The test method of claim 13, further comprising:
inputting the input signal, which transitions from a high level to a low level, to the memory device;
inputting a fifth delayed clock, to which a fifth delay time equal to a fifth integer multiple of the unit delay time is applied, to the memory device;
based on the output signal having a high level being output from the memory device in response to the fifth delayed clock, inputting a sixth delayed clock, to which a sixth delay time equal to a sixth integer multiple of the unit delay time is applied, to the memory device, wherein the output signal having a low level is output in response to the sixth delayed clock; and
determining a hold time of the memory device based on the unit delay time, the fifth delay time, and the sixth delay time.

16. A test device for a memory device, the test device comprising:
an oscillator configured to output an oscillation signal;
a first exclusive OR (XOR) gate configured to perform an XOR operation between a clock signal and an output signal output from the memory device;
a first chain circuit and a second chain circuit configured to output delayed clocks in which different delay times are respectively applied to the clock signal;
a second XOR gate configured to perform an XOR operation between a signal output from the first chain circuit and a signal output from the second chain circuit; and
an output circuit configured to determine a period of the oscillation signal,
wherein the output circuit is configured to:
determine an access time of the memory device based on a number of rising edges of the oscillation signal that occur while a first operation signal output from the first XOR gate is maintained at a high level, and the period of the oscillation signal; and
determine a unit delay time based on a number of rising edges of the oscillation signal that occur while a second operation signal output from the second XOR gate is maintained at a high level.

17. The test device of claim 16, further comprising:
a control logic circuit connected to the first chain circuit and the second chain circuit,
wherein the control logic circuit is configured to:
control the first chain circuit to output a first delayed clock to which a first delay time, equal to a first integer multiple of the unit delay time, is applied; and
control the second chain circuit to output a second delayed clock to which a second delay time, equal to a second integer multiple of the unit delay time, is applied, and
wherein the second XOR gate is configured to output the second operation signal as a result of an XOR operation between the first delayed clock and the second delayed clock.

18. The test device of claim 17, wherein the control logic circuit, in a state in which the input signal transitions from a low level to a high level, is configured to:
control the first chain circuit to output a third delayed clock to which a third delay time equal to a third integer multiple of the unit delay time is applied;
based on the output signal having a high level being output in response to the third delayed clock, control the first chain circuit to output a fourth delayed clock, to which a fourth delay time equal to a fourth integer multiple of the unit delay time is applied, wherein the output signal having a low level is output in response to the fourth delayed clock; and
determine a setup time of the memory device based on the unit delay time, the third integer multiple, and the fourth integer multiple.

19. The test device of claim 18, wherein the control logic circuit, in a state in which the input signal transitions from a high level to a low level, is configured to:
control the first chain circuit to output a fifth delayed clock to which a fifth delay time equal to a fifth integer multiple of the unit delay time is applied;
based on the output signal having a high level being output in response to the fifth delayed clock, control the first chain circuit to output a sixth delayed clock, to which a sixth delay time equal to a sixth integer multiple of the unit delay time is applied, wherein the output signal having a low level is output in response to the sixth delayed clock; and
determine a hold time of the memory device based on the unit delay time, the fifth integer multiple, and the sixth integer multiple.

20. The test device of claim 16, further comprising:
a second multiplexer electrically connected to the first XOR gate and the second XOR gate; and
an AND gate electrically connected between the second multiplexer and the output circuit,
wherein the output circuit is configured to count a number of rising edges output through the AND gate while a signal, output from the second multiplexer, of the oscillation signal is maintained at a high level.
